(19) United States
(12) Patent Application Publication
(10) Pub. No.: US 2025/0212454 A1
(43) Pub. Date: Jun. 26, 2025

(54) SEMICONDUCTOR DEVICE

(71) Applicant: Renesas Electronics Corporation, Tokyo (JP)

(72) Inventors: Atsushi SAKAI, Tokyo (JP); Katsumi EIKYU, Tokyo (JP)

(21) Appl. No.: 18/950,421

(22) Filed: Nov. 18, 2024

(30) Foreign Application Priority Data
Dec. 22, 2023 (JP) 2023-217475

(51) Int. Cl. H01L 29/78; H01L 29/06; H01L 29/40; H01L 29/66

(52) U.S. Cl. CPC H10D 30/668; H10D 30/0297; H10D 62/127; H10D 64/117

(57) ABSTRACT

A semiconductor device with high performance is provided. A semiconductor device according to the present disclosure includes a semiconductor substrate having a plurality of trenches provided along a first direction, a field plate electrode having a plurality of recess portions and a plurality of thinning-out portions which are alternately disposed in the first direction, and being provided in the trench, an oxide film provided on the field plate electrode, and a gate electrode formed on the oxide film and disposed in each of the recess portions. In the adjacent trenches, the gate electrodes are disposed to be shifted in the first direction.

### CROSS-REFERENCE TO RELATED APPLICATIONS

The disclosure of Japanese Patent Application No. 2023-217475 filed on Dec. 22, 2023 including the specification, drawings and abstract is incorporated herein by reference in its entirety.

### BACKGROUND

The present disclosure relates to a semiconductor device, and particularly to a semiconductor device such as a metal-oxide-semiconductor (MOS) transistor including a field plate electrode.

There are disclosed techniques listed below.
[Patent Document 1] Japanese Unexamined Patent Application Publication No. 2022-149431

Patent Document 1 discloses a trench-gate type MOSFET (Metal-Oxide-Semiconductor Field-Effect transistor). This MOSFET includes a source electrode provided on a semiconductor substrate and a drain electrode provided on a back surface side of the substrate. Moreover, the MOSFET includes a gate electrode which extends in a longitudinal direction of a trench. In addition, in an embodiment, the MOSFET has a trench field plate structure in which a buried electrode is formed below the gate electrode.

### SUMMARY

In a semiconductor device such as a MOS transistor described above, further improvement in performance has been demanded.

Other objects and novel features will become apparent from the description of the present specification and the accompanied drawings.

A semiconductor device according to an aspect of the present disclosure includes a semiconductor substrate having a plurality of trenches provided along a first direction, a field plate electrode having a plurality of recess portions and a plurality of thinning-out portions which are alternately disposed in the first direction, and being provided in the trench, an oxide film provided on the field plate electrode, and a gate electrode formed on the oxide film and disposed in each of the recess portions. In the adjacent trenches, the gate electrodes are disposed to be shifted in the first direction.

According to the present disclosure, it is possible to provide a semiconductor device with higher performance.

### BRIEF DESCRIPTION OF THE DRAWINGS

FIG. 1 is a top plan view schematically illustrating a configuration of a MOS transistor according to a first embodiment.

FIG. 2 is a cross-sectional view taken along an X-Z plane, schematically illustrating the configuration of the MOS transistor according to the first embodiment.

FIG. 3 is a cross-sectional view taken along a Y-Z plane, schematically illustrating the configuration of the MOS transistor according to the first embodiment.

FIG. 4 is a top plan view schematically illustrating a configuration of a MOS transistor according to a second embodiment.

FIG. 5 is a cross-sectional view taken along the X-Z plane, schematically illustrating the configuration of the MOS transistor according to the second embodiment.

FIG. 6 is a cross-sectional view taken along the Y-Z plane, schematically illustrating the configuration of the MOS transistor according to the second embodiment.

FIG. 7 is a top plan view schematically illustrating a configuration of a MOS transistor according to a third embodiment.

FIG. 8 is a cross-sectional view taken along the X-Z plane, schematically illustrating the configuration of the MOS transistor according to the third embodiment.

FIG. 9 is a cross-sectional view taken along the Y-Z plane, schematically illustrating the configuration of the MOS transistor according to the third embodiment.

FIG. 10 is a cross-sectional view taken along the Y-Z plane, schematically illustrating a configuration of a MOS transistor according to a first modification.

FIG. 11 is a perspective view schematically illustrating a configuration of a trench in a manufacturing process.

FIG. 12 is a graph indicating characteristics of the MOS transistor.

### DETAILED DESCRIPTION

In the following, embodiments will be described with reference to the attached drawings. Note that the drawings are simplified, and the technical scope of the embodiments should not be narrowly interpreted on the basis of these drawings. In addition, the same constituent elements indicated in the drawings are designated by the same reference signs, and their duplicate explanations are omitted.

### First Embodiment

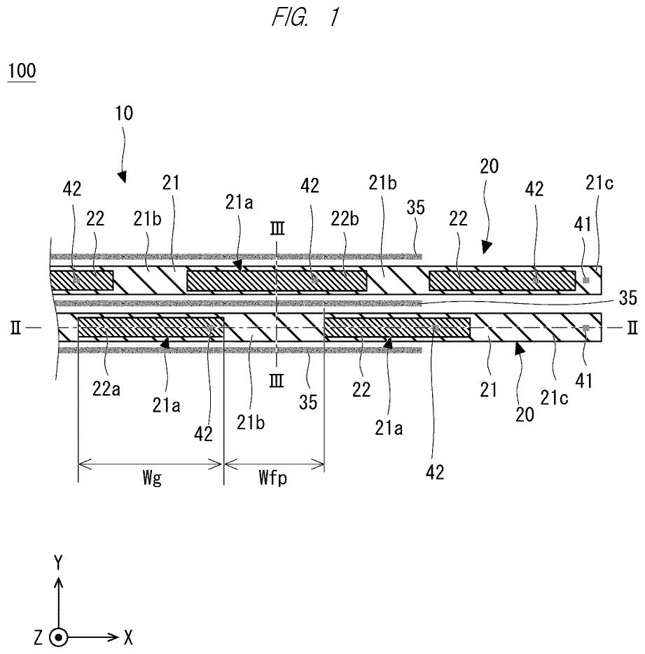

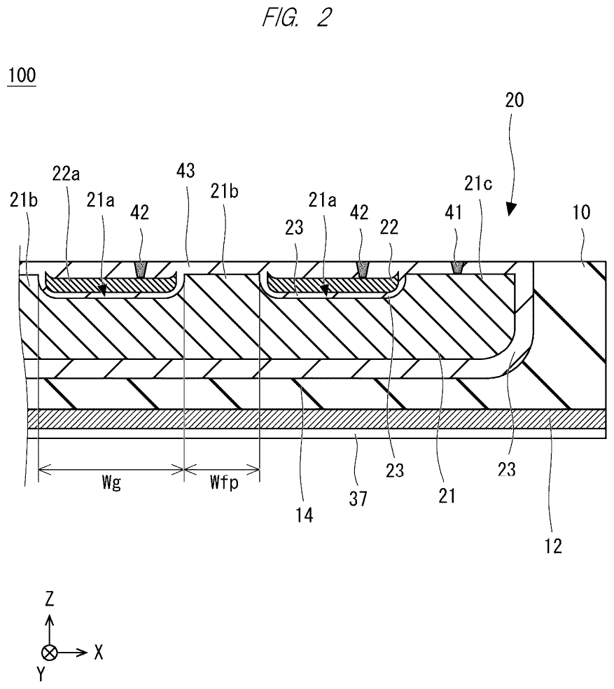

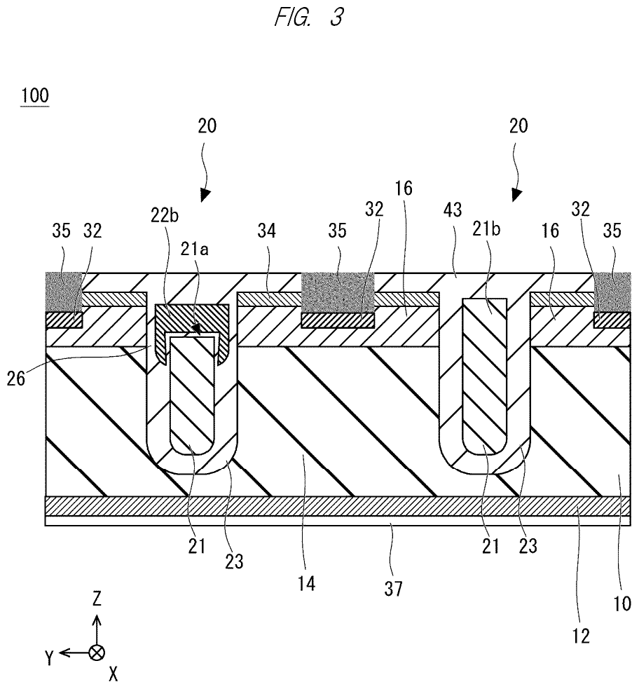

A MOS transistor according to the present embodiment is a trench gate MOSFET having a trench formed in a semiconductor substrate. For example, the MOS transistor is a vertical type power device. With regard to a configuration of the MOS transistor, a description will be given with reference to FIG. 1 to FIG. 3. FIG. 1 is an X-Y plan view schematically illustrating a configuration of a MOS transistor 100. FIG. 2 is an X-Z cross-sectional view schematically illustrating a cross section taken along a line II-II in FIG. 1. FIG. 3 is a Y-Z cross-sectional view schematically illustrating a cross section taken along a line III-III in FIG. 1.

Note that, in the following figures, for clarification of description, an XYZ-three-dimensional orthogonal coordinate system is illustrated. More specifically, a thickness direction (depth direction) of a semiconductor substrate 10 is represented as a Z direction, and a plane orthogonal to the Z direction is represented as the X-Y plane. In the X-Y plane, an X direction represents a longitudinal direction of a trench 20, and a Y direction represents a lateral direction (width direction) of the trench 20. The X direction is orthogonal to the Y direction. Note that a plan on a +Z side of the semiconductor substrate 10 is referred to as a front surface and a plane on a −Z side as a back surface.

The MOS transistor 100 is a power device having, for example, a vertical MOSFET structure. The MOS transistor 100 includes the semiconductor substrate 10, the trench 20, a field plate (FP) electrode 21, a gate electrode 22, a source 34, a gate contact 42, a source contact 35, an FP contact 41, a drain 37, an insulating film 43, and the like. Note that, although illustration is omitted, patterns of upper-layer wirings which are connected to respective contacts are formed on the insulating film 43. An upper-layer wiring is formed by a pattern of a metal film such as Al, for example.

For example, the semiconductor substrate 10 is a silicon substrate and has the drain 37 provided on the back surface side thereof. Above the drain 37, an N+ layer 12, an N− drift layer 14, and a p type channel layer 16 are provided.

As illustrated in FIG. 1, in the semiconductor substrate 10, a plurality of trenches 20 are formed. Note that, in FIG. 1, two trenches 20 only are illustrated, but the number of trenches 20 is not limited to any particular number. In actual use, the plurality of trenches 20 are disposed side by side in the Y direction. More specifically, the two trenches 20 illustrated in FIG. 1 are disposed side by side in a repeated manner. If the trench 20 is changed in its depth direction, length, and the number of trenches (chip area), an on-resistance Ron of the MOS transistor 100 can be changed.

As described above, each of the trenches 20 is formed along the X direction. In addition, the plurality of trenches 20 are disposed side by side in the Y direction with an interval. As illustrated in FIG. 3, between the two adjacent trenches 20, the source 34 and a back gate 32 are disposed. The source 34 is disposed on the p type channel layer 16.

In the trench 20, the gate electrode 22, a field plate electrode (hereinafter, referred to as a FP electrode) 21, and an oxide film 23 are provided. The FP electrode 21 and the gate electrode 22 are each formed of a polysilicon film, for example. The oxide film 23 is a silicon dioxide film (SiO2 film) or the like. The oxide film 23 serves as a gate insulating film 26 at the periphery of the gate electrode 22.

The FP electrode 21 is disposed below the gate electrode 22. The oxide film 23 is interposed between the FP electrode 21 and the gate electrode 22. In the Z direction, the FP electrode 21 is disposed between the drain 37 and the gate electrode 22. The insulating film 43 is formed on upper surfaces of the gate electrode 22 and the FP electrode 21. The insulating film 43 serves as an oxide film formed on a protruding portion 21c to be described later. For example, the insulating film 43 is a silicon oxide film formed in such a manner as to cover the gate electrode 22, the FP electrode 21, the source 34, and the like. The insulating film 43 is formed on the front surface of the semiconductor substrate 10.

The FP electrode 21 includes a recess portion 21a, a thinning-out portion 21b, and the protruding portion 21c. The FP electrode 21 protrudes toward the front surface of the semiconductor substrate 10 at a terminal portion thereof in the X direction. A portion of which the FP electrode 21 protrudes upward at the terminal portion thereof in the X direction serves as the protruding portion 21c. In addition, the recess portion 21a is a portion which is recessed toward a lower side of the FP electrode 21. One FP electrode 21 has a plurality of recess portions 21a provided side by side in the X direction. Each of the recess portions 21a has the gate electrode 22 formed therein.

A portion between the two adjacent recess portions 21a serves as the thinning-out portion 21b. The thinning-out portion 21b is a region in which the gate electrode 22 is not formed. One trench 20 has a plurality of thinning-out portions 21b disposed side by side in the X direction. In one trench 20, the recess portion 21a and the thinning-out portion 21b are alternately disposed in the X direction. In one trench 20, a plurality of gate electrodes 22 are provided to be spaced from each other in the X direction.

The protruding portion 21c and the thinning-out portion 21b are substantially same in height. As illustrated in FIG. 1 and FIG. 2, a size of the recess portion 21a in the X direction is set to Wg. In addition, in the X direction, the size of the thinning-out portion 21b is set to Wfp. The thinning-out portion 21b is a portion of which the FP electrode 21 protrudes.

The FP contact 41 is provided on the FP electrode 21. The FP contact 41 is disposed on the protruding portion 21c. The FP contact 41 is formed of a metal film and the like and passes through the insulating film 43. As such, the FP contact 41 is connected to the FP electrode 21, resulting in achieving supply of a potential to the FP electrode 21.

The gate contact 42 is provided on the recess portion 21a. In other words, the gate contact 42 is formed on the gate electrode 22. The gate contact 42 is formed of a metal film and the like and passes through the insulating film 43. The gate contact 42 is connected to the gate electrode 22, resulting in achieving supply of a gate potential to the gate electrode 22.

One trench 20 has the plurality of recess portions 21a and the plurality of gate electrodes 22 provided therein. Each of the recess portions 21a has the gate electrode 22 formed therein. Accordingly, the plurality of gate electrodes 22 are disposed side by side in a line along the X direction. In the X direction, the plurality of gate electrodes 22 are disposed to be spaced from each other.

Moreover, as illustrated in FIG. 1, as for the adjacent two trenches 20, the gate electrodes 22 are disposed to be shifted in the X direction. For clarification of description, in FIG. 1, the gate electrode 22 of one trench 20 of the two trenches 20 is also referred to as a gate electrode 22a, and the gate electrode 22 of the other trench 20 is also referred to as a gate electrode 22b. A position of the gate electrode 22a of the one trench 20 in the X direction is different from a position of the gate electrode 22b of the other trench 20 in the X direction.

In the X direction, a region in which the gate electrode 22b is provided is disposed in a region in which the gate electrode 22a is not provided. Similarly, in the X direction, a region in which the gate electrode 22a is provided is disposed in a region in which the gate electrode 22b is not provided. Moreover, an end portion of the gate electrode 22a and an end portion of the gate electrode 22b in the X direction are disposed overlapping with each other.

The sources 34 are provided on both sides of the trench 20 in the Y direction. In other words, in the Y direction, the source 34 is formed between the two trenches 20. The source 34 is disposed on the p type channel layer 16. In addition, the back gate 32 is formed below the source 34. As illustrated in FIG. 1, in the Y direction, on both sides of the trenches 20, the source contacts 35 are provided. In other words, the source contact 35 is disposed between the adjacent two trenches 20. The source contact 35 passes through the insulating film 43. The source contact 35 is connected to the source 34, thereby supplying a source potential.

Thus, the FP electrode 21 of the MOS transistor 100 includes the recess portions 21a and the thinning-out portions 21b which are alternately disposed in the X direction. Also, the recess portion 21a has the gate electrode 22 formed therein. The FP electrode 21 has the thinning-out portion 21b for thinning out the gate electrode 22 provided therein. In other words, in the thinning-out portion 21b, the gate electrode 22 is not formed. With this configuration, it is possible to achieve the MOS transistor 100 with high performance. For example, since an area of the gate electrode 22 can be made small, a capacitance Cgd between the gate and the drain can be made small. As a result, it is possible to reduce a switching loss.

In the following description, a performance index of the MOS transistor 100 will be described. As the performance index of the power device, it is important to obtain not only a specific on-resistance Rsp, but also a value Ron*Qgd that takes the switching loss into account. Note that a value Ron indicates an on-resistance between the drain and the source, and a value Qgd indicates an electric charge amount accumulated between the gate and the drain. The value Qgd is substituted with the value Ron*Cgd as a more simplified index, since it needs a switching measurement. In addition, when the chip area is changed, the values Ron and Cgd can also be changed. However, the value Ron*Cgd per unit area of a device becomes substantially constant. Note that the chip area changes according to change in the number of the trenches 20 and the size of the trench 20 in the X direction.

In the first embodiment, provision of the thinning-out portion 21b in the trench 20 achieves such a configuration that the gate electrode 22 is thinned out. With this configuration, the area of the gate electrode 22 can be reduced, so that the capacitance Cgd and the capacitance Cgs can be reduced. Note that the value Cgs is a capacitance between the gate and the source. For example, since the capacitances Cgd and Cgs are proportional to the value Wg, reduction of the value Wg allows the capacitances Cgd and Cgs to be made small. In other words, increasing the value Wfp allows the capacitances Cgd and Cgs to be made small.

Meanwhile, as the gate area is reduced, the specific on-resistance Rsp accordingly increases. The specific on-resistance Rsp becomes a value corresponding to the channel resistance Rch, the drift resistance Rdr, and the substrate resistance Rsub. For example, the specific on-resistance Rsp is substantially equal to a total sum (Rch+Rdr+Rsub) of the channel resistance Rch, the drift resistance Rdr, and the substrate resistance Rsub. Here, although the channel resistance Rch changes according to the size Wg, the drift resistance Rdr and the substrate resistance Rsub do not depend on the size Wg. Hence, when the repeated cycle (Wg+Wfp) is optimized, it is possible to reduce a total switching loss represented by Rsp*Cgd*Cgs. According to the operation frequency of the device, it is possible to adjust an optimum pitch. Also, shifting the repeated cycle between the adjacent trenches enables prevention of increase of the specific on-resistance Rsp.

It is preferable to make the size Wfp small. For example, in the X direction, the sizes of the recess portion 21a and the thinning-out portion 21b can be set to a size to such an extent as not to cause a problem in terms of processing restriction of a process. For example, a range from a submicron size to several micrometers can be set. In a case in which the capacitance is desired to be decreased, the size Wg is preferably made small. In a case in which the on-resistance is not desired to be increased, the size Wg is preferably made large.

### Second Embodiment

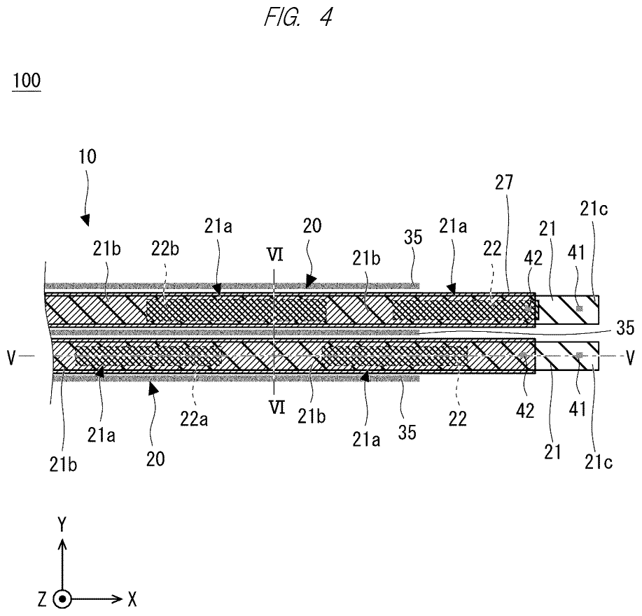

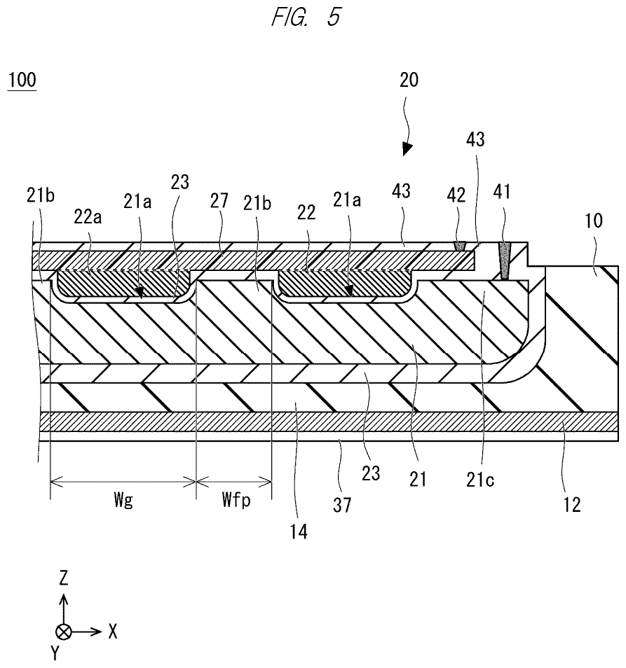

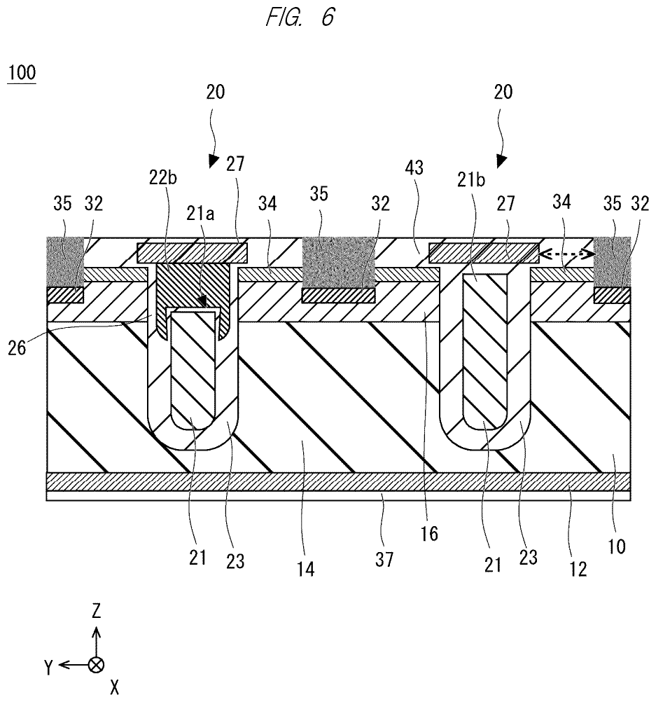

A configuration of a MOS transistor 100 according to a second embodiment will be described with reference to FIG. 4 to FIG. 6. FIG. 4 is an X-Y plan view schematically illustrating the configuration of the MOS transistor 100. FIG. 5 is a cross-sectional view taken along the X-Z plane, schematically illustrating a cross section taken along a line V-V of FIG. 4. FIG. 6 is a cross-sectional view taken along the Y-Z plane, schematically illustrating a cross section taken along a line VI-VI of FIG. 4.

In the second embodiment, a gate connecting electrode 27 for connecting the plurality of gate electrodes 22 is added. Since the basic configuration other than the gate connecting electrode 27 is the same as that of the first embodiment, the repetitive description thereof will be omitted as appropriate.

The gate connecting electrode 27 is formed on the gate electrode 22. The gate connecting electrode 27 is formed along the Y direction. The gate connecting electrode 27 is formed above the trench 20. In the X-Y plan view, the gate connecting electrode 27 is formed extending over the plurality of recess portions 21a and the plurality of thinning-out portions 21b. The gate connecting electrode 27 is disposed above the protruding portion 21c. The gate connecting electrode 27 is a polysilicon film integrally formed with the plurality of gate electrodes 22.

The gate connecting electrode 27 is formed at a position higher than the front surface of the semiconductor substrate 10. The gate connecting electrode 27 is covered with the insulating film 43. In the thinning-out portion 21b, the gate connecting electrode 27 is disposed above the FP electrode 21. In the thinning-out portion 21b, the oxide film 23 is interposed between the gate connecting electrode 27 and the FP electrode 21.

In this manner, since the gate connecting electrode 27 connects the plurality of gate electrodes 22, the number of gate contacts 42 can be reduced. For example, in the first embodiment, the gate contact 42 is provided with respect to each of the gate electrodes 22. In contrast, in the second embodiment, it is sufficient if one gate contact 42 is provided in one trench 20. In other words, routing of the upper-layer wiring with respect to the gate contact 42 for each of the gate electrode 22 is not required.

With this configuration adapted, it is possible to simplify the pattern of the upper-layer wiring which is to be connected to the contact. For example, it is possible to prevent a wiring resistance RsAl of the upper-layer wiring of the source from being increased. Moreover, increase of a parasitic capacitance CgsAl between the gate and the source in the upper-layer wiring can be prevented. Hence, the MOS transistor 100 with higher performance can be achieved.

In order to form the gate connecting electrode 27 indicated in the second embodiment, it is sufficient if one photo mask is added to the configuration in the first embodiment. In other words, it is sufficient that an etching step of the gate polysilicon film is changed to photoresist etching, instead of an etch-back step for the entire surface.

### Third Embodiment

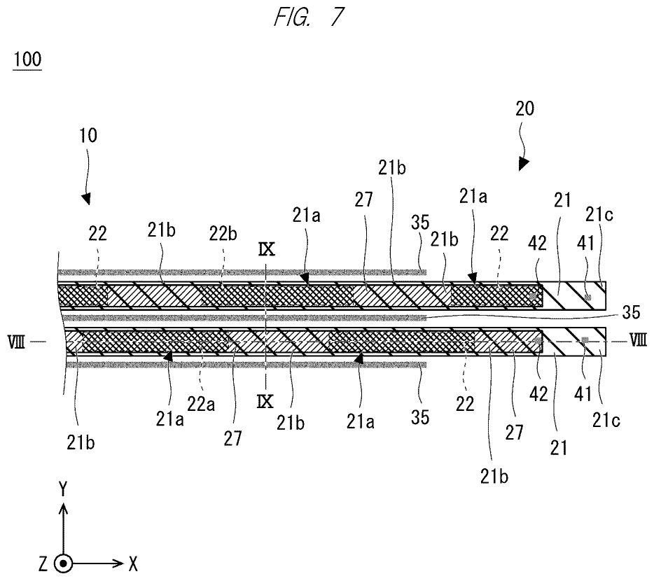

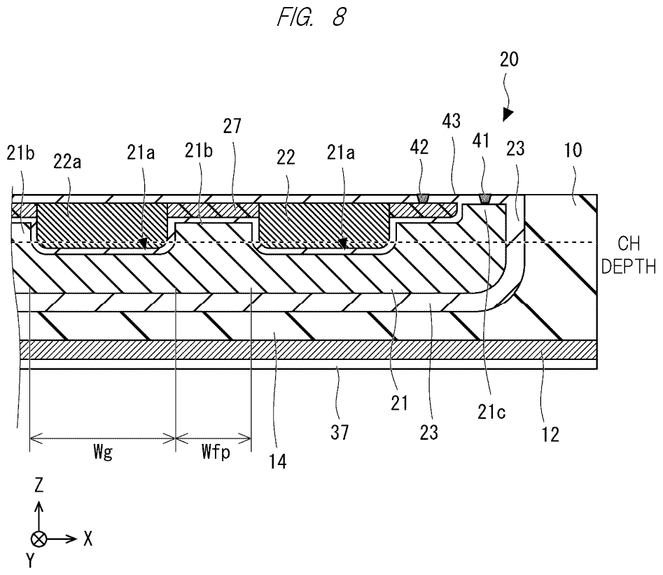

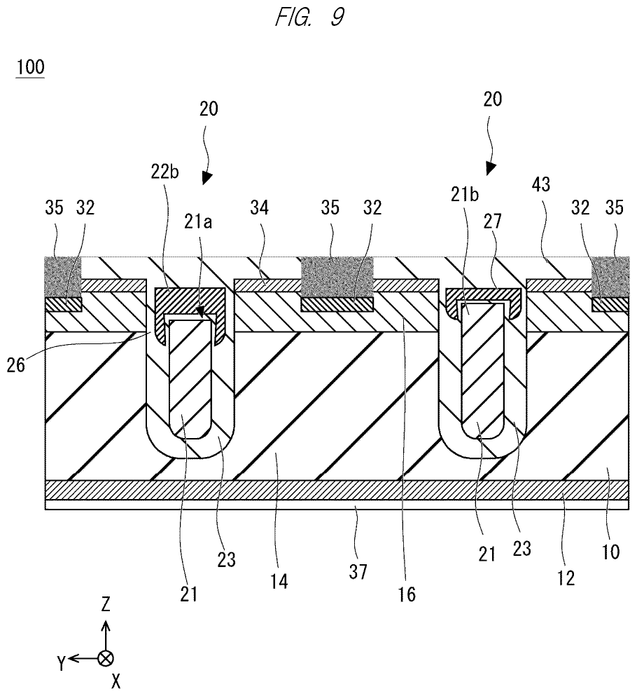

A configuration of a MOS transistor 100 according to a third embodiment will be described with reference to FIG. 7 to FIG. 9. FIG. 7 is an X-Y plan view schematically illustrating the configuration of the MOS transistor 100 according to the third embodiment. FIG. 8 is a cross-sectional view taken along the X-Z plane, schematically illustrating a cross section taken along a line VIII-VIII of FIG. 7. FIG. 9 is a cross-sectional view taken along the Y-Z plane, schematically illustrating a cross section taken along a line IX-IX of FIG. 7.

In the third embodiment, the configuration of the gate connecting electrode 27 differs from that of the second embodiment. The basic configuration other than the gate connecting electrode 27 is the same as those in the first and the second embodiments, the description thereof will be omitted as appropriate.

In the third embodiment, the gate connecting electrode 27 is formed at a height lower than the front surface of the semiconductor substrate 10. More specifically, the gate connecting electrode 27 is formed at the same height as the protruding portion 21c. As illustrated in FIG. 8, the FP electrode 21 is formed in three steps. The thinning-out portion 21b is lower than the protruding portion 21c and higher than the recess portion 21a. In other words, the thinning-out portion 21b is positioned in height between the recess portion 21a and the protruding portion 21c. Then, the gate connecting electrode 27 is formed at the thinning-out portion 21b. The gate connecting electrode 27 is a polysilicon film formed integrally with the gate electrode 22. The gate connecting electrode 27 is disposed in the trench 20.

Then, the gate connecting electrode 27 connects the gate electrodes 22 provided in the adjacent recess portions 21a. Moreover, the gate connecting electrode 27 is formed in a region shallower than a channel depth (CH depth). Accordingly, the gate connecting electrode 27 does not perform a MOS operation. In other words, in the thinning-out portion 21b, a current in the longitudinal direction along the channel does not flow. Compared with the first embodiment, it is possible to obtain an effect of reducing the capacitance Cgd to substantially the same degree as that in the first embodiment, although the effect of reducing the capacitance Cgs is smaller than that in the first embodiment.

With this configuration, short circuiting between the gate and the source can be prevented. Specifically, a positional displacement may occur in the mask in the photolithography step. When the positional displacement occurs in the Y direction, a distance between the gate connecting electrode 27 and the source contact 35 (see a dashed line in FIG. 6) in the Y direction becomes short. Consequently, short circuiting between the gate and the source may occur.

In the present embodiment, the gate connecting electrode 27 is formed lower than the front surface of the semiconductor substrate 10. Hence, the short circuiting between the gate and the source caused by the positional displacement can be prevented. In other words, it is possible to prevent the contact between the source contact and the gate electrode caused by the positional displacement of the mask.

Note that, in order to achieve the configuration of the third embodiment, it is sufficient that one additional mask is applied in the etching step for the polysilicon film serving as the FP electrode 21. In other words, two masks, i.e., the mask for forming the thinning-out portion 21b and the mask for forming the recess portion 21a are used, so that the FP electrode 21 can have the three-step configuration as illustrated in FIG. 8.

### First Modification

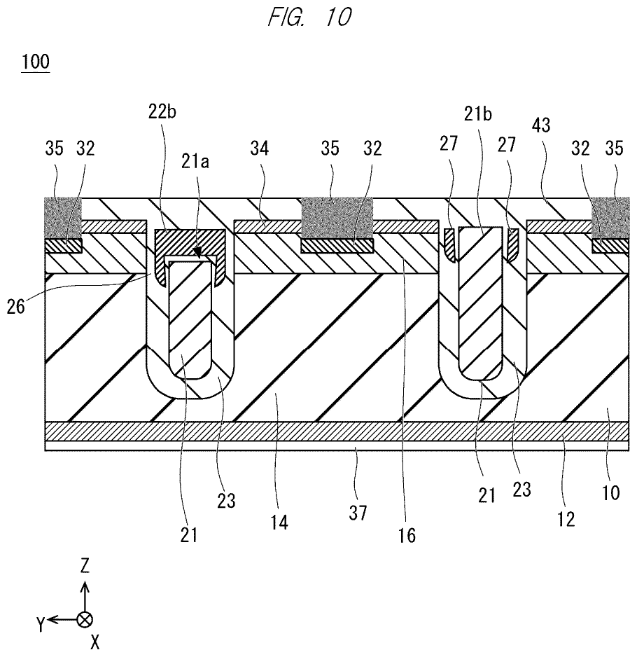

A configuration of a first modification of the third embodiment will be described with reference to FIG. 10. FIG. 10 is a cross-sectional view taken along the Y-Z plane, schematically illustrating the configuration of the MOS transistor. In the first modification, the thinning-out portion 21b is formed at the same height as that of the protruding portion 21c. Accordingly, the X-Z cross section has the same configuration as that of FIG. 2. Also, in the thinning-out portion 21b, as illustrated in FIG. 10, the gate connecting electrode 27 is formed on each side of the FP electrode 21 in the Y direction.

The gate connecting electrode 27 is formed at a height lower than the front surface of the semiconductor substrate 10. The gate connecting electrode 27 is formed in a region shallower than the channel depth.

Even with such a configuration described above, it is possible to obtain the same effect as that described above. It is possible to prevent short circuiting between the gate and the source caused by the positional displacement. In addition, it is possible to obtain the effect of reducing the capacitance Cgd to the same degree as that in the first embodiment.

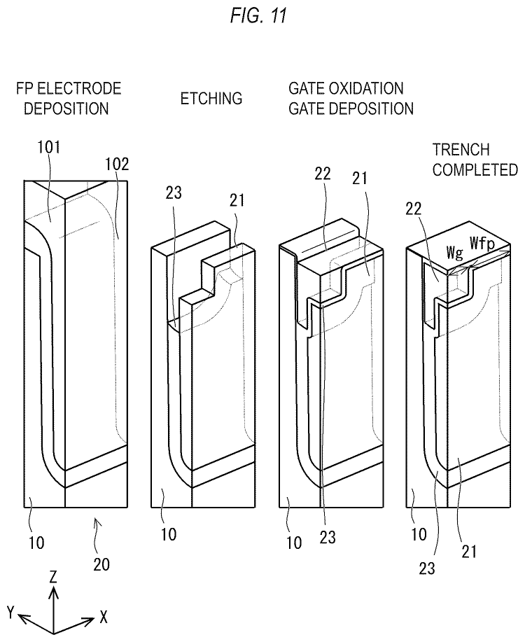

A manufacturing process for the MOS transistor 100 according to the first modification of the third embodiment will be described with reference to FIG. 11. FIG. 11 is a perspective view schematically illustrating a configuration of the trench 20, and indicates a cross section of the trench 20 in each step.

First, in an FP electrode deposition step, a polysilicon film 102 serving as an FP electrode is formed in the trench 20. More specifically, in the trench 20, a silicon oxide film 101 is formed on the front surface of the semiconductor substrate 10. The polysilicon film 102 is formed on the silicon oxide film 101. The polysilicon film 102 is formed so as to protrude outside the trench 20.

Subsequently, in an etching step, the silicon oxide film 101 and the polysilicon film 102 are subjected to etching. As a result, the FP electrode 21 and the oxide film 23 are formed. In this step, the front surface of the semiconductor substrate 10 is also etched. Here, in order to make the polysilicon film 102 have a step, a mask may be added. In addition, when etching for the silicon oxide film 101 adopts isotropic etching, it is possible to make a boundary portion at the step even.

Subsequently, after the front surface of the FP electrode 21 is oxidized, the gate electrode 22 is formed (gate deposition step). In other words, the polysilicon film 102 is deposited on the oxide film 23, and the gate electrode 22 is thereby formed. Then, the oxide film is formed on the front surface, and the trench 20 is thereby completed.

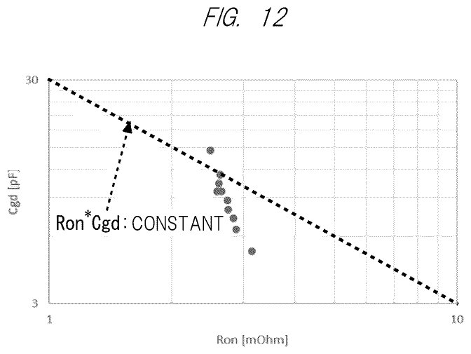

FIG. 12 is a graph indicating characteristics of the MOS transistor 100. FIG. 12 is a graph indicating a verification result obtained by taking a cell portion of the MOS transistor 100 according to the third embodiment into account through the TCAD (Technology Computer Aided Design). In FIG. 12, the abscissa axis represents the on-resistance Ron, and the ordinate axis represents the capacitance Cgd between the gate and the drain.

In the configuration that the thinning-out portion 21b is not provided, the on-resistance Ron and the capacitance Cgd between the gate and the drain have a trade-off relation. Accordingly, the value Ron*Cg indicated in FIG. 12 is constant, so that the verification result lies in a dashed line. In contrast, in the present embodiment, it is possible to reduce the capacitance Cgd, suppressing increase of the on-resistance Ron, compared with the trade-off relation between the on-resistance Ron and the capacitance Cgd in a case in which a cell area is changed by adjusting the values Wg and Wfp.

Note that, in the MOS transistor according to the embodiments above, a configuration in which the conductive type (p type or n type) of each of a semiconductor substrate, a semiconductor layer, a diffusion layer (diffusion region), and the like is inverted may be adopted. As such, in a case in which either one of the n type and the p type is set to the first conductive type and the other one is set to the second conductive type, the first conductive type can be set to the p type, and the second conductive type can also be set to the n type. Conversely, the first conductive type can be set to the n type, and the second conductive type can also be set to the p type.

In the foregoing, the invention made by the inventor of the present invention has been concretely described based on the embodiments. However, it is needless to say that the present invention is not limited to the foregoing embodiments and various modifications and alterations can be made within the scope of the present invention.

What is claimed is:

1. A semiconductor device comprising:
a semiconductor substrate having a plurality of trenches provided along a first direction;
a field plate electrode having a plurality of recess portions and a plurality of thinning-out portions which are alternately disposed in the first direction, and being provided in the trench;
an oxide film provided on the field plate electrode; and
a gate electrode formed on the oxide film and disposed in each of the recess portions,
wherein, in the adjacent trenches, the gate electrodes are disposed to be shifted in the first direction.

2. The semiconductor device according to claim 1,
wherein the field plate electrode has a protruding portion which protrudes upward toward a front surface side of the semiconductor substrate at a terminal portion thereof in the first direction.

3. The semiconductor device according to claim 2, further comprising:
a gate connecting electrode provided so as to connect the gate electrodes disposed in the plurality of recess portions in one of the trenches.

4. The semiconductor device according to claim 3,
wherein the thinning-out portion is formed lower than the protruding portion,
wherein the gate connecting electrode is formed in a region shallower than a channel depth in the trench, and
wherein the gate connecting electrode is formed at the thinning-out portion so as to connect the gate electrodes provided in the adjacent recess portions.

5. The semiconductor device according to claim 4,
wherein the gate electrodes in the adjacent trenches are formed such that ends thereof overlap with each other in the first direction.

6. The semiconductor device according to claim 3,
wherein the thinning-out portion is formed at the same height as the protruding portion,
wherein the gate connecting electrode is formed in a region shallow than a channel depth in the trench, and
wherein the gate connecting electrode is disposed on each side of the field plate electrode in a second direction orthogonal to the first direction in plan view.

7. The semiconductor device according to claim 6,
wherein the gate electrodes in the adjacent trenches are formed such that ends thereof overlap with each other in the first direction.

8. The semiconductor device according to claim 3,
wherein the gate connecting electrode is formed at a height higher than the front surface of the semiconductor substrate, and
wherein, in plan view, the gate connecting electrode is formed along the first direction, in such a manner as to extend over the plurality of recess portions.

9. The semiconductor device according to claim 8,
wherein the gate electrodes in the adjacent trenches are formed such that ends thereof overlap with each other in the first direction.

10. The semiconductor device according to claim 1,
wherein a plurality of the gate electrodes are provided in the trench so as to be spaced apart from each other in the first direction.

11. The semiconductor device according to claim 10,
wherein the gate electrodes in the adjacent trenches are formed such that ends thereof overlap with each other in the first direction.
